(19) United States
(12) Patent Application Publication
(10) Pub. No.: US 2011/0183239 A1
(43) Pub. Date: Jul. 28, 2011

(54) Photolithography Mask, Blank Photomask, Reflective Photomask, and Methods of Manufacturing the Same

(76) Inventors: Chang-Min Park, Hwaseong-si (KR); Joo-On Park, Suwon-si (KR); Jeong-Ho Yeo, Suwon-si (KR)

(21) Appl. No.: 12/963,064

(22) Filed: Dec. 8, 2010

(30) Foreign Application Priority Data
Jan. 28, 2010 (KR) 10-2010-0007983

(51) Int. Cl. G03F 1/00

(52) U.S. Cl. 430/5

(57) ABSTRACT

Photolithography masks include an optically transparent substrate having a plurality of fiducial position aligning marks on sidewalls thereof. A reflective layer is also provided on an upper surface of the optically transparent substrate. The reflective layer includes a composite of a lower reflective layer of a first material and an upper reflective layer of a second material different from the first material, on the lower reflective layer. The lower reflective layer may include molybdenum and the upper reflective layer may include silicon. An anti-reflective layer is provided on the reflective layer.

### REFERENCE TO PRIORITY APPLICATION

This application claims priority to Korean Patent Application No. 10-2010-0007983, filed Jan. 28, 2010, the contents of which are hereby incorporated herein by reference.

### FIELD

Embodiments of the inventive concept relate to blank photomasks, reflective photomasks, and methods of manufacturing the same.

### BACKGROUND

Photolithography technology is essential for fabricating a highly integrated semiconductor device. In particular, technology for manufacturing a photomask is being considered more important.

### SUMMARY OF THE INVENTION

Photolithography masks according to embodiments of the invention include an optically transparent substrate having a plurality of fiducial position aligning marks on sides thereof. A reflective layer is also provided on an upper surface of the optically transparent substrate. The reflective layer includes a composite of a lower reflective layer of a first material and an upper reflective layer of a second material different from the first material, on the lower reflective layer. The lower reflective layer may include molybdenum and the upper reflective layer may include silicon. An anti-reflective layer is provided on the reflective layer.

According to additional embodiments of the invention, the photolithography mask also includes a capping layer on the reflective layer and a buffer layer on the capping layer. The capping and buffer layers extend between the reflective layer and the anti-reflective layer. The capping layer may include silicon dioxide and the buffer layer may include a metal (e.g., ruthenium). In addition, the anti-reflective layer may include chromium, chromic oxides and/or tantalum nitride.

According to still further embodiments of the invention, the reflective layer includes a composite of multiple lower reflective layers and multiple upper reflective layers arranged in an alternating sequence. The reflective layer may also have a thickness in a range from about 6.7 nm to about 6.8 nm. Furthermore, the reflective layer may be formed as a composite of the lower reflective layer, the upper reflective layer and a boron carbide layer. This boron carbide layer may be sandwiched between the lower and upper reflective layers in some embodiments of the invention.

According to still further embodiments of the invention, the plurality of fiducial position aligning marks include a refractory metal on a sidewall of the optically transparent substrate. These aligning marks are sufficiently thick to provide a step height difference between the sidewall of the optically transparent substrate and a surface of the fiducial position aligning marks.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIGS. 1A and 1B are schematic perspective views of a blank photomask and a reflective photomask including an optical pattern according to embodiments of the inventive concept, respectively;

FIGS. 2A to 2D show examples of fiducial position aligning marks of various shapes according to embodiments of the inventive concept;

FIG. 3 is a conceptual diagram illustrating a process of aligning a blank photomask using a fiducial position aligning mark according to embodiments of the inventive concept;

FIG. 4 is a flowchart schematically illustrating a process of manufacturing a blank photomask including a fiducial position aligning mark according to embodiments of the inventive concept; and

FIG. 5 is a flowchart schematically illustrating a process of manufacturing a reflective photomask including an optical pattern using a blank photomask including a fiducial position aligning mark according to embodiments of the inventive concept.

### DETAILED DESCRIPTION OF EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity.

It will be understood that when an element or layer is referred to as being “on” another element or layer, it can be directly on the other element or layer or intervening elements or layers may be present. In contrast, when an element is referred to as being “directly on” another element or layer, there are no intervening elements or layers present. Like numerals refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to perspective views and plan views those are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

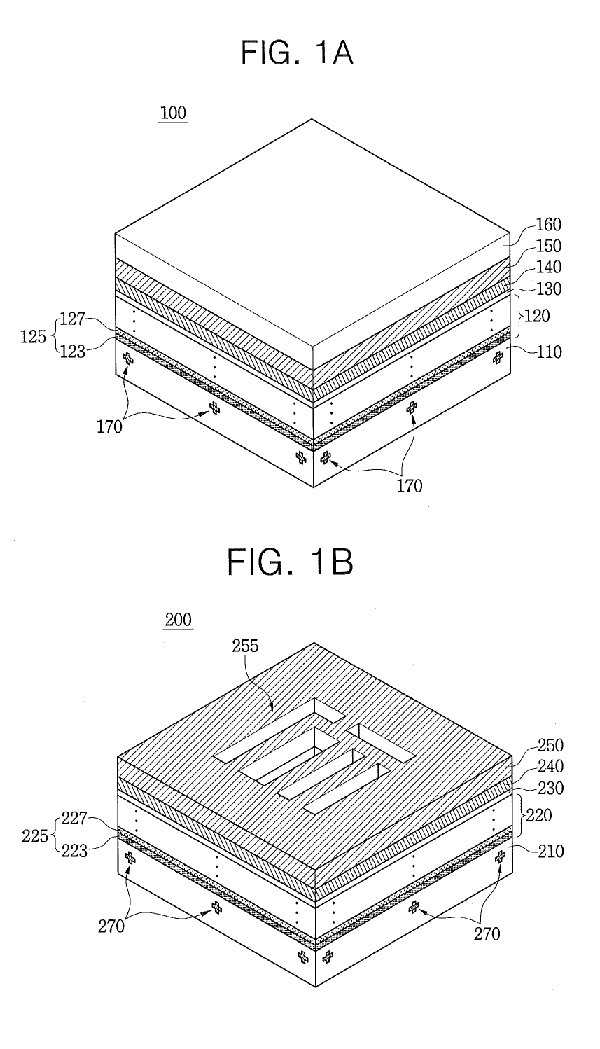

FIG. 1A is a schematic perspective view of a blank photomask according to embodiments of the inventive concept, and FIG. 1B is a schematic perspective view of a reflective photomask including an optical pattern according to embodiments of the inventive concept. Referring to FIG. 1A, a blank photomask 100 may include a photomask substrate 110, a reflective layer 120, an anti-reflective layer 150, an electron beam resist layer 160, and also at least one fiducial position aligning mark 170 formed on a side of the photomask substrate 110. The blank photomask 100 may further include a capping layer 130 and a buffer layer 140 formed between the reflective layer 120 and the anti-reflective layer 150.

The photomask substrate 110 may include glass or an inorganic compound, such as ceramic, etc. For example, the photomask substrate 110 may include a low temperature expansion material (LTEM). The LTEM may include silica doped with titanium, and so on. The photomask substrate 110 may be formed in a quadrangular shape having a proper thickness. For example, the photomask substrate 110 may be formed as a quadrangle having a thickness of about ¼ inch and a size of 6 square inches.

The reflective layer 120 may be formed by stacking multiple unit reflective layers 125 including a lower reflective layer 123 and an upper reflective layer 127. The lower reflective layer 123 may include molybdenum, and the upper reflective layer 127 may include silicon. The reflective layer 120 may be formed by stacking about 40 unit reflective layers 125. The unit reflective layers 125 may be formed to a thickness of about 6.7 to 6.8 nm, which is close to half of the wavelength of main light used in lighting systems. For example, assuming that light used in a lighting system is extreme ultraviolet (EUV) light, the unit reflective layers 125 may be formed to a thickness of about 6.7 to 6.8 nm because the wavelength of the EUV light is about 13.5 nm. In the unit reflective layers 125, a molybdenum layer of about 11 atomic layers and a silicon layer of about 15 atomic layers may be formed as the lower reflective layer 123 and the upper reflective layer 127, respectively. The molybdenum layer of about 11 atomic layers has a thickness of about 2.65 to 2.7 nm, and the silicon layer of about 15 atomic layers has a thickness of about 4.0 to 4.1 nm. The thickness of each material layer may vary according to energy. The thicknesses correspond to a stable energy state at a normal temperature. In another embodiment, the unit reflective layers 125 each may include three or more kinds of material layers. In this case, a boron carbide (B₄C) layer may be disposed on and under the unit reflective layers 125, or inserted between the lower reflective layer 123 and the upper reflective layer 127. In other words, the unit reflective layers 125 may include the lower reflective layer 123, the boron carbide (B₄C) layer, and the upper reflective layer 127. The boron carbide layer does not need to be formed to one thickness but may be formed to various thicknesses. For example, the thickness may be 0.25 nm or 0.40 nm. In this case, the boron carbide layer having a thickness of 0.25 nm may be formed on the lower reflective layer 123, and the upper reflective layer 127 may be formed on the boron carbide layer. Also, the boron carbide layer having a thickness of 0.40 nm may be formed on the upper reflective layer 127, and another lower reflective layer 123 may be formed on the boron carbide layer. In all these cases, the lower reflective layer 123 and the upper reflective layer 127 may both vary in thickness. For example, the thickness of the lower reflective layer 123 may be reduced to about 2.09 nm, and the thickness of the upper reflective layer 127 may be increased to about 4.14 nm. In other words, the respective thicknesses may increase and decrease.

The capping layer 130 may be formed of silicon dioxide (SiO₂) to a thickness of about 10 to 30 nm. The capping layer 130 may be used as a patterning-stop layer when the anti-reflective layer 150 and the buffer layer 140 are patterned. Also, the capping layer 130 may protect the reflective layer 120. For example, even after the anti-reflective layer 150 is patterned, the capping layer 130 may protect the reflective layer 120 from external chemical and physical attacks. Further, the capping layer 130 may increase adhesion of the reflective layer 120 and the buffer layer 140 or the anti-reflective layer 150. The capping layer 130 may be formed of a material transparent to EUV light.

The buffer layer 140 may compensate for adhesion and thermal expansivity between the capping layer 130 and the anti-reflective layer 150. The buffer layer 140 may be formed of a refractory metal, for example, ruthenium. The buffer layer 140 may be formed to a thickness of about 50 nm.

The anti-reflective layer 150 is also referred to as a light absorbing layer or an absorbing layer. The anti-reflective layer 150 may include chromium, chromic oxides or tantalum nitride. The anti-reflective layer 150 may be formed to a thickness of about 70 nm. Chromium, which is widely used in the field of photomask manufacturing technology, is readily worked and low priced. Tantalum nitride may be worked to a smaller thickness than chromium or chromic oxides and thus can improve the resolution of an optical pattern.

In the electron beam resist layer 160 may be formed to an electron beam resist pattern through electron beam lithography, development process, and etc. The electron beam resist pattern may be used forming an optical pattern from the anti-reflective layer 150. The term “blank photomask” 100 may denote that no optical pattern is formed, and the electron beam resist layer 160 is formed on the uppermost portion.

The at least one fiducial position aligning mark 170 may be formed on at least one of the four sides of the photomask substrate 110. To be specific, the fiducial position aligning mark 170 may be formed on only one of the four sides of the photomask substrate 110, or all of the sides. Also, the fiducial position aligning mark 170 may be formed at a random position on a side of the photomask substrate 110. FIG. 1A shows an example in which three fiducial position aligning marks 170 are formed at the left end, right end, and middle on a side of the photomask substrate 110.

The fiducial position aligning mark 170 may be referred to determine a fiducial position used when at least one piece of photomask coordinate information is generated or read. Specifically, the photomask coordinate information may be generated or referred to in processes of manufacturing a photomask. For example, photomask coordinate information may be generated or referred to in a process of forming the reflective layer 120, a process of forming the capping layer 130, a process of forming the buffer layer 140, a process of forming the anti-reflective layer 150, a process of lithographing an optical pattern using an electron beam, etc., a process of forming the optical pattern, and/or a check process of monitoring each process.

In processes of manufacturing a reflective photomask, the interrelationship of conventional photomask coordinate information is not taken into consideration. This is because material layers are continuously formed on the photomask, and alignment marks keep disappearing. In a process of inspecting a pattern of a photomask and other inspection processes, independent coordinate information is generated and used according to each inspection process. In other words, pieces of any coordinate information that may be generated in the processes of manufacturing a reflective photomask have no relationship with each other. An alignment mark, with which a fiducial position can be aligned, needs to be on a surface other than the upper surface of the photomask so that pieces of any coordinate information generated or used in respective processes can have relationships with each other.

Referring to FIG. 1B, a reflective photomask 200 according to embodiments of the inventive concept may include a photomask substrate 210, a reflective layer 220, an anti-reflective pattern 250 having an optical pattern 255, and also at least one fiducial position aligning mark 270 formed on a side of the photomask substrate 210. The reflective photomask 200 may further include a capping layer 230 and a buffer layer pattern 240 formed between the reflective layer 220 and the anti-reflective pattern 250.

The reflective layer 220 may be formed by stacking multiple unit reflective layers 225 including a lower reflective layer 223 and an upper reflective layer 227, which may be understood with reference to FIG. 1A and the description. The optical pattern 255 may be included in the anti-reflective pattern 250 and the buffer layer pattern 240. The optical pattern 255 may expose a surface of the capping layer 230. The fiducial position aligning mark 270 may be understood with reference to FIG. 1A and the description, and will be described in detail later.

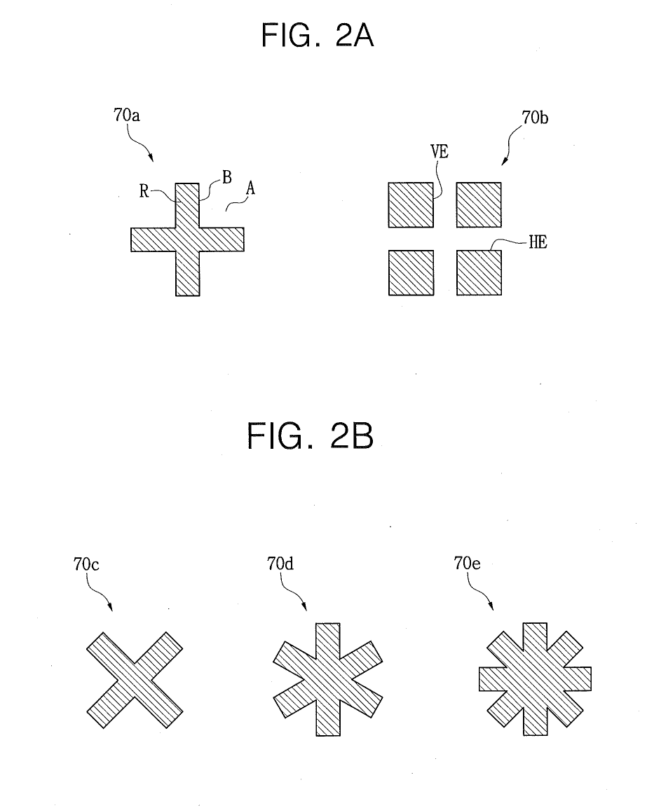

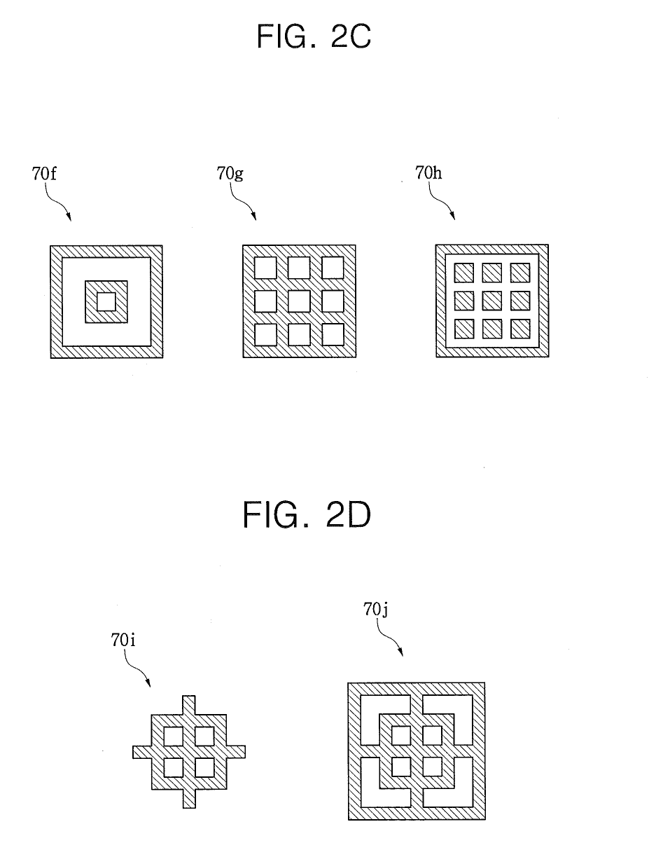

FIGS. 2A to 2D show examples of fiducial position aligning marks of various shapes according to embodiments of the inventive concept. Referring to FIGS. 2A to 2D, fiducial position aligning marks 70a to 70j include a reflective portion R that reflects light, an absorptive portion A that does not reflect light, and a boundary B between the reflective portion R and the absorptive portion A. The reflective portion R may include a metal, for example, chromium, molybdenum, or the other refractory metals. The reflective portion R and the absorptive portion A may be formed on different surface levels. In other words, the reflective portion R and the absorptive portion A may have a step difference. In addition, the fiducial position aligning marks 70a to 70j may be mesa shapes. The fiducial position aligning marks 70a to 70j may be formed as an intaglio or a relief. Here, the boundary B may be considered an edge. In other words, the boundary B may be a corner at which surfaces come in contact with each other. Since reflected light will be diffused at the boundary B, one side of the boundary B may reflect light, and the other side of the boundary B may not reflect light. The fiducial position aligning marks 70a to 70j include at least one edge VE extending in, the vertical direction in a plan view. To improve performance of the fiducial position aligning marks 70a to 70j, the fiducial position aligning marks 70a to 70j may include two or more edges VE. Also, to further improve performance of the fiducial position aligning marks 70a to 70j of a photomask, the fiducial position aligning marks 70a to 70j may include at least one edge HE extending in the horizontal direction in the plan view. Needless to say, to further improve performance of the fiducial position aligning marks 70a to 70j, the fiducial position aligning marks 70a to 70j may include two or more edges HE extending in the horizontal direction. The edges VE and HE may be patterns of various bar or rectangular shapes extending in the horizontal or vertical direction. There may be multiple patterns of bar or quadrangular shapes, which may be separate from each other or at least two of which may cross each other. Referring to FIG. 2A, the fiducial position aligning marks 70a and 70b according to embodiments of the inventive concept may be formed in a “+” shape and an inverted “+” shape. Referring to FIG. 2B, the fiducial position aligning marks 70c to 70e according to embodiments of the inventive concept may be formed in a cross shape, a snow crystal shape, a double cross shape, and so on. Needless to say, the inverses of these shapes can also be formed. Referring to FIG. 2C, the fiducial position aligning marks 70f to 70h according to embodiments of the inventive concept may be formed in a double quadrangular shape, a lattice shape, and an island shape. Referring to FIG. 2D, the fiducial position aligning marks 70i and 70j according to embodiments of the inventive concept may be formed in a shape in which bar patterns cross a quadrangle, a shape in which bar patterns cross double quadrangles, and so on. In addition, fiducial position aligning marks of various shapes including the reflective portion R, the absorptive portion A, and the vertical edge VE and the horizontal edge HE at the boundary B between the reflective portion R and the absorptive portion A may be employed.

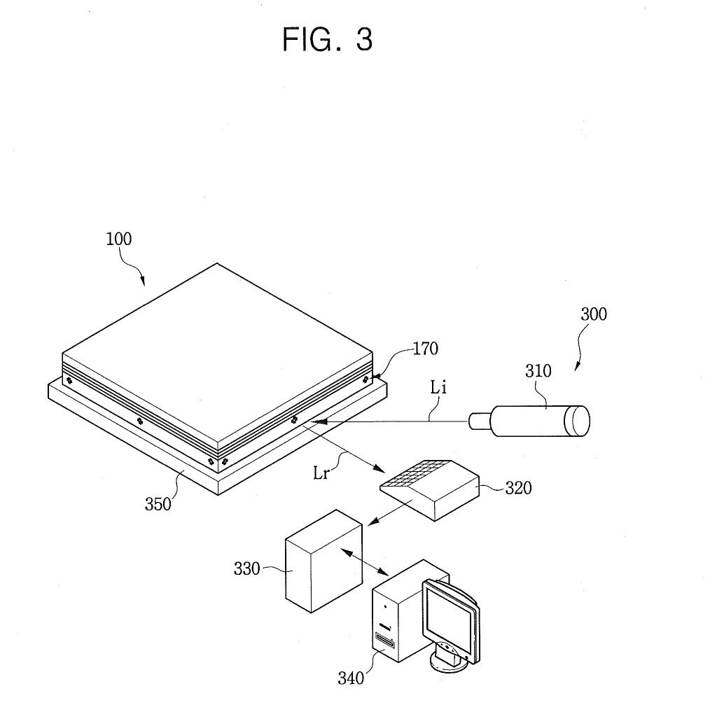

FIG. 3 is a conceptual diagram illustrating a process of aligning a blank photomask using a fiducial position aligning mark according to embodiments of the inventive concept. Referring to FIG. 3, to align a blank photomask 100 at accurate coordinates, a photomask alignment apparatus 300 is used. The photomask alignment apparatus 300 may include a light emitter 310, a light receiver 320, and a coordinate information generator 330. The coordinate information generator 330 may be connected with a visual monitor 340. The light emitter 310 may radiate light Li to the fiducial position aligning mark 170, and the light receiver 320 may receive light Lr reflected by the fiducial position aligning mark 170. The coordinate information generator 330 may generate coordinate information of the blank photomask 100 on the basis of position information of the fiducial position aligning mark 170. Also, the coordinate information generator 330 may compare pieces of coordinate information with each other. When the coordinate information generator 330 refers to coordinate information used in a previous process, a photomask stage 350 may move in X, Y and Z directions to align the blank photomask 100 at accurate coordinates. The blank photomask 100 may be fixed on the photomask stage 350 according to the principle of vacuum or electrostatic discharge.

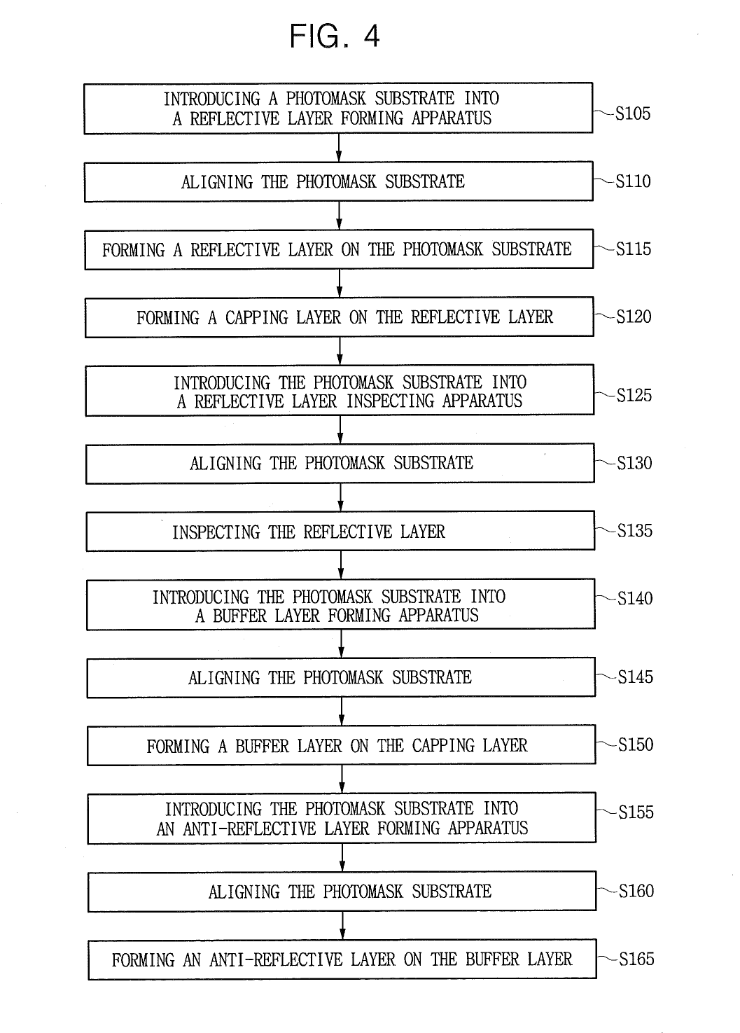

FIG. 4 is a flowchart schematically illustrating a process of manufacturing a blank photomask including a fiducial position aligning mark according to embodiments of the inventive concept. Referring to FIG. 4, the process of manufacturing a blank photomask including a fiducial position aligning mark may include introducing a photomask substrate having a fiducial position aligning mark on a side into a reflective layer forming apparatus (S105), aligning the photomask substrate in the reflective layer forming apparatus (S110), forming a reflective layer on the photomask substrate (S115), forming a capping layer on the reflective layer (S120), introducing the photomask substrate on which the reflective layer is formed into a reflective layer inspection apparatus (S125), aligning the photomask substrate in the reflective layer inspection apparatus (S130), inspecting the reflective layer (S135), introducing the photomask substrate into a buffer layer forming apparatus (S140), aligning the photomask substrate in the buffer layer forming apparatus (S145), forming a buffer layer on the capping layer on the photomask substrate (S150), introducing the photomask substrate into an anti-reflective layer forming apparatus (S155), aligning the photomask substrate in the anti-reflective layer forming apparatus (S160), and forming an anti-reflective layer on the buffer layer on the photomask substrate (S165). The sequence of the operations may be changed, and the respective operations may be omitted. In the alignment operations S110, S130, S145 and S160, the photomask substrate may be aligned using the fiducial position aligning mark according to embodiments of the inventive concept as fiducial coordinates.

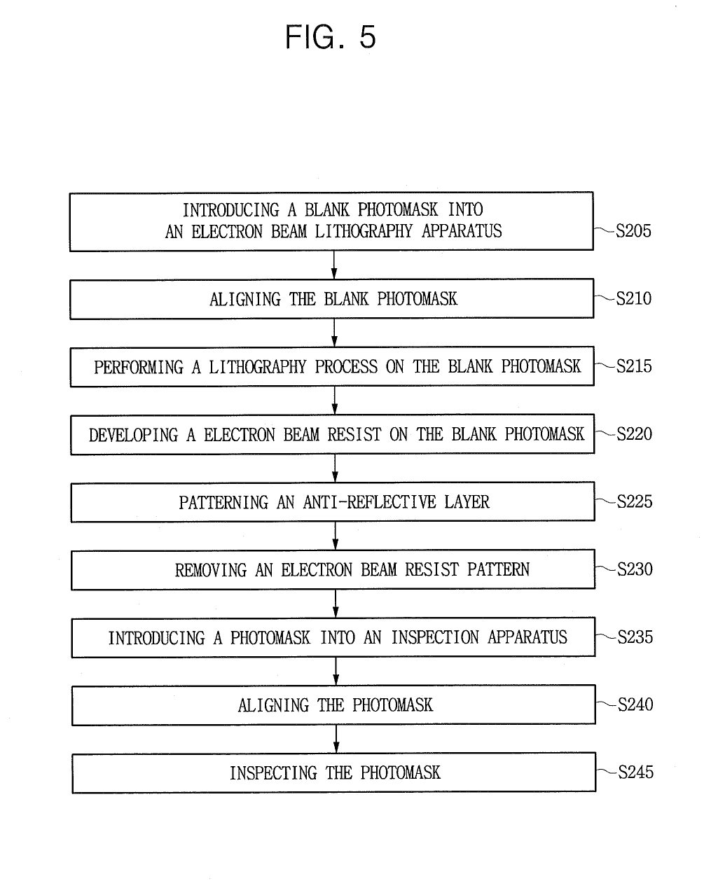

FIG. 5 is a flowchart schematically illustrating a process of manufacturing a reflective photomask including an optical pattern using a blank photomask including a fiducial position aligning mark according to embodiments of the inventive concept. Referring to FIG. 5, the process of manufacturing a reflective photomask including a fiducial position aligning mark according to embodiments of the inventive concept includes introducing a blank photomask having a photomask substrate, a reflective layer, a capping layer, a buffer layer, an anti-reflective layer, an electron beam resist layer, and a fiducial position aligning mark into an electron beam lithography apparatus (S205), aligning the blank photomask in the electron beam lithography apparatus (S210), lithographing an electron beam resist on the blank photomask using an electron beam (S215), developing the blank photomask including the electron beam resist lithographed using an electron beam to form an electron beam resist pattern (S220), patterning the anti-reflective layer using the electron beam resist pattern as a patterning mask to form an optical pattern (S225), and removing the electron beam resist pattern (S230). The process may further include introducing the reflective photomask into an inspection apparatus (S235), aligning the reflective photomask in the inspection apparatus (S240), and inspecting the reflective photomask (S245).

Referring back to FIGS. 3 to 5, in a process of manufacturing or inspecting a photomask, defective coordinate information of the blank photomask 100 aligned with the fiducial position aligning mark 170 may be generated or analyzed. For example, a process of forming a reflective layer on a photomask substrate may be performed after the fiducial position aligning mark 170 is aligned at a fiducial position. Also, for example, inspecting the blank photomask 100 may include aligning the fiducial position aligning mark 170 at the fiducial position, and then generating and analyzing defective coordinate information. In addition, a process of forming a capping layer, a buffer layer, and/or an anti-reflective layer on a reflective layer may be performed after the fiducial position aligning mark 170 is aligned at the fiducial position. According to embodiments of the inventive concept, the blank photomask 100 is aligned at fixed fiducial coordinates in all processes. Thus, coordinates of a defect, etc. of the blank photomask 100 are not calculated in each process but are absolute coordinates that are constant in all processes. When defective coordinates, etc. that the blank photomask 100 has are known in advance, it is possible to prevent the defect from having influence on a process of manufacturing the blank photomask 100 into a photomask having an optical pattern. For example, the blank photomask 100 is a square and symmetrical in four directions. In other words, the blank photomask 100 is manufactured into a photomask having an optical pattern with one of the four directions selected and set as a fiducial direction. The fiducial direction may be, for example, a downward direction. At this time, it is possible to predict whether or not the defect will have influence on the optical pattern of the complete photomask with reference to the coordinate information of the defect. For example, it is possible to predict that the defect will be exposed between an anti-reflective layer patterns or covered by the anti-reflective layer pattern.

The names, functions, etc. of components that are not indicated by reference numerals in the drawings can be readily understood from other drawings and the descriptions.

As described above, processes for a blank photomask and a reflective photomask according to embodiments of the inventive concept can be performed while pieces of accurate coordinate information that can be used in all the processes are generated and compared. Consequently, accurate process monitoring is enabled, an optimum layout and manufacturing method can be selected, and a defect rate is reduced to improve productivity.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

1. A photolithography mask, comprising:
an optically transparent substrate having a plurality of fiducial position aligning marks on sides thereof;
a reflective layer on an upper surface of said optically transparent substrate, said reflective layer comprising a composite of a lower reflective layer of a first material and an upper reflective layer of a second material different from the first material, on the lower reflective layer; and
an anti-reflective layer on said reflective layer.

2. The mask of claim 1, wherein the lower reflective layer comprises molybdenum and the upper reflective layer comprises silicon.

3. The mask of claim 1, further comprising:
a capping layer on said reflective layer; and
a buffer layer on said capping layer, said capping and buffer layers extending between said reflective layer and said anti-reflective layer.

4. The mask of claim 3, wherein said capping layer comprises silicon dioxide and wherein said buffer layer comprises a metal.

5. The mask of claim 3, wherein said capping layer comprises silicon dioxide and wherein said buffer layer comprises a ruthenium.

6. The mask of claim 3, wherein said anti-reflective layer comprises chromium, chromic oxides and/or tantalum nitride.

7. The mask of claim 1, wherein said reflective layer comprises a composite of the lower reflective layer, the upper reflective layer and a boron carbide layer.

8. The mask of claim 7, wherein the boron carbide layer extends between the lower and upper reflective layers.

9. The mask of claim 1, wherein the plurality of fiducial position aligning marks comprises a metal on a sidewall of the optically transparent substrate.

10. The mask of claim 9, wherein the plurality of fiducial position aligning marks are sufficiently thick to provide a step height difference between the sidewall of the optically transparent substrate and a surface of the fiducial position aligning marks.

11. A blank photomask, comprising:
a substrate having a fiducial position aligning mark on at least one side;
a reflective layer formed on the substrate;
a capping layer formed on the reflective layer;
a buffer layer formed on the capping layer;
an anti-reflective layer formed on the buffer layer; and
an electron beam resist layer formed on the anti-reflective layer.

12. The blank photomask according to claim 11, wherein the substrate comprises a plurality of fiducial position aligning marks on one side.

13. The blank photomask according to claim 11, wherein the substrate comprises the fiducial position aligning marks formed on at least two sides.

14. The blank photomask according to claim 11, wherein the fiducial position aligning mark comprises a reflective portion and an absorptive portion.

15. The blank photomask according to claim 14, wherein the reflective portion includes a metal.

16. The blank photomask according to claim 14, wherein the fiducial position aligning mark further comprises a boundary between the reflective portion and the absorptive portion, and
wherein the boundary comprises at least one pair of parallel edges.

17. The blank photomask according to claim 16, wherein the edges extend in a vertical direction in a plan view.

18. The blank photomask according to claim 17, wherein the boundary further comprises at least one pair of edges extending in a horizontal direction.

19. The blank photomask according to claim 18, wherein the reflective portion is formed in a bar or rectangular shape by the edges extending in the vertical direction and the edges extending in the horizontal direction.

20. A reflective photomask, comprising:
a photomask substrate having a fiducial position aligning mark on a side;
a reflective layer formed on the photomask substrate;
a capping layer formed on the reflective layer;
a buffer layer pattern formed on the capping layer; and
an anti-reflective layer pattern formed on the buffer layer pattern,
wherein the buffer layer pattern and the anti-reflective layer pattern are optical patterns.

21.-30. (canceled)
